(19) United States
(12) Patent Application Publication
(10) Pub. No.: US 2026/0123229 A1
(43) Pub. Date: Apr. 30, 2026

(54) DISPLAY PANEL, MANUFACTURING METHOD THEREOF, AND DISPLAY DEVICE

(71) Applicant: HKC CORPORATION LIMITED, Shenzhen (CN)

(72) Inventors: TING ZHOU, Shenzhen (CN); Jing Li, Shenzhen (CN); Min Huang, Shenzhen (CN); Tianjun Huang, Shenzhen (CN); Haijiang Yuan, Shenzhen (CN)

(21) Appl. No.: 19/370,743

(22) Filed: Oct. 28, 2025

(30) Foreign Application Priority Data
Oct. 31, 2024 (CN) 202411553020.1

(51) Int. Cl. H10K 59/38; H10K 59/12; H10K 59/122; H10K 59/80

(52) U.S. Cl. CPC H10K 59/38; H10K 59/1201; H10K 59/122; H10K 59/8792

(57) ABSTRACT

A display panel, a manufacturing method thereof, and a display device are disclosed. The display panel includes a substrate, a light-emitting element layer, multiple pixel-defining layers, an encapsulation layer, and a color filter layer. The light-emitting element layer includes multiple light-emitting elements that are arranged in an array on the substrate. The multiple pixel-defining layers are disposed on the substrate. Adjacent two light-emitting elements are separated by a corresponding pixel-defining layer. The encapsulation layer is disposed on the multiple light-emitting elements and the multiple pixel-defining layers. The color filter layer is disposed on the encapsulation layer. Multiple color filter dots are disposed on a surface of the color filter layer facing away from the substrate side. At each same aperture region or each same non-aperture region, a color of the multiple color filter dots differs from a color of the color filter layer.

### CROSS-REFERENCE TO RELATED APPLICATIONS

The present application claims the priority and benefit of Chinese patent application number 2024115530201, titled “Display Panel, Manufacturing Method Thereof, and Display Device” and filed on Oct. 31, 2024 with China National Intellectual Property Administration, the entire contents of which are incorporated herein by reference.

### TECHNICAL FIELD

The present application relates to the field of display technology, and more particularly relates to a display panel, a manufacturing method thereof, and a display device.

### BACKGROUND

The description provided in this section is intended for the mere purpose of providing background information related to the present application but does not necessarily constitute prior art.

With the continuous development of Organic Light-Emitting Diode (OLED) display technology, OLED has become increasingly prevalent in displays for smartphones, tablets, computers, televisions, etc. OLED displays offer several advantages such as being thin and light, having high contrast, fast response, wide viewing angles, high brightness, and full-color capability. In order to reduce the reflection of external light inside the OLED display, the related solution is to attach a circular polarizer to the light-emitting surface of the OLED display. However, this solution causes significant light loss due to the circular polarizer, which reduces the light output efficiency. Another approach involves disposing a color filter on the light-emitting surface of the OLED display to enhance light output efficiency. Additionally, by disposing a black matrix (BM), the reflection of environmental light in the OLED display can be reduced.

However, although the black matrix can absorb some of the environmental light, some light still directly enters the interior of the display panel from the color filter piece, causing issues such as light reflection and glare.

### SUMMARY

It is therefore one purpose of the present application to provide a display panel, a method for manufacturing the same, and a display device. By adding color filter dots in the color filter layer, glare can be reduced and the display effect of the display panel under strong light can be improved.

The present application discloses a display panel, the display panel including a plurality of aperture regions and a plurality of non-aperture regions. The display panel includes a substrate, a light-emitting element layer, a plurality of pixel-defining layers, an encapsulation layer, and a color filter layer. The light-emitting element layer includes a plurality of light-emitting elements. The plurality of light-emitting elements are arranged in an array on the substrate and are respectively disposed in the plurality of aperture regions. The plurality of pixel-defining layers are disposed on the substrate and are respectively disposed in the plurality of non-aperture regions. Two adjacent light-emitting elements are separated by the corresponding pixel-defining layer. The encapsulation layer is disposed on the plurality of light-emitting elements and the plurality of pixel-defining layers. The color filter layer is disposed on the encapsulation layer. A plurality of color filter dots are disposed on a surface of the color filter layer facing away from the substrate. At the same aperture region or the same non-aperture region, a color of the plurality of color filter dots is different from that of the color filter layer.

In some embodiments, the color filter layer includes a plurality of black matrices and a plurality of color filter pieces. The plurality of black matrices are respectively disposed in the plurality of non-aperture regions. The plurality of color filter pieces are respectively disposed in the plurality of aperture regions. Adjacent color filter pieces are separated by the corresponding black matrix. In each non-aperture region, a plurality of recesses are defined in the surface of the corresponding black matrix facing away from the substrate. The plurality of color filter dots are respectively disposed in the plurality of recesses. A material of each color filter dot is identical with that of any one of the plurality of color filter pieces.

In some embodiments, the plurality of color filter dots include a plurality of blue filter dots. The plurality of color filter pieces include a plurality of blue filter pieces. The plurality of blue filter dots are formed simultaneously with the plurality of blue filter pieces in the same manufacturing procedure.

In some embodiments, the display panel further includes a cover plate, which is disposed on the side of the color filter layer facing away from the substrate. The plurality of blue filter dots are formed on the cover plate. After the plurality of blue filter dots are formed, a plurality of black matrices are formed on the plurality of blue filter dots, such that a recess is formed in each black matrix at a position corresponding to each of the blue filter dots.

In some embodiments, the radial width of each color filter dot is less than or equal to a, where a is a ratio of the width of the corresponding black matrix to the number of the color filter dots distributed on the corresponding black matrix. The projection of each color filter dot on the substrate is in a hexagonal, circular, or elliptical shape.

In some embodiments, within one non-aperture region, the total area of the plurality of color filter dots is less than or equal to two-thirds of the area of the corresponding black matrix.

In some embodiments, the color filter layer includes a plurality of black matrices and a plurality of color filter pieces. The plurality of black matrices are respectively disposed in the plurality of non-aperture regions. The plurality of color filter pieces are respectively disposed in the plurality of aperture regions. Adjacent color filter pieces are separated by the corresponding black matrix. The plurality of color filter pieces include green filter pieces, red filter pieces, and blue filter pieces. In the surface of each of the plurality of color filter pieces facing away from the substrate, a plurality of recesses are also formed, and the plurality of color filter dots are respectively disposed in the plurality of recesses. The plurality of color filter dots are blue filter dots or transparent filter dots.

In some embodiments, on each of the color filter pieces, the total projected area of all the blue filter dots on the substrate accounts for 8% to 10% of the projected area of the color filter piece on the substrate.

The present application further discloses a method for manufacturing a display panel, wherein the display panel comprises a plurality of aperture regions and a plurality of non-aperture regions, and the method for manufacturing the display panel comprises the following operations:
forming a plurality of pixel-defining layers and a light-emitting element layer on a substrate, where the light-emitting element layer includes a plurality of light-emitting elements;
forming an encapsulation layer on the plurality of light-emitting elements and the plurality of pixel-defining layers;
forming a color filter layer on the encapsulation layer; and
forming a plurality of color filter dots on the surface of the color filter layer facing away from the substrate, where at a position of the same aperture region or the same non-aperture region, the color of the plurality of color filter dots is different from that of the color filter layer.

The present application further discloses a display device, the display device including a driving circuit and the above-described display panel, where the driving circuit is configured to drive the display panel for display.

In the present application, a plurality of color filter dots are arranged on the surface of the color filter layer, and the color of the color filter dots is different from that of the color filter layer. When ambient light is incident on the display panel, it is first filtered by the plurality of color filter dots, thereby reducing the reflective effect on the color filter layer. For each aperture region, when a plurality of color filter dots are disposed on the color filter layer in this aperture region, since the plurality of color filter dots have a different color from that of the color filter layer, part of the environmental light is filtered by the color filter dots and then absorbed by the underlying color filter layer, so that part of the environmental light cannot enter the display panel and be reflected. Furthermore, the plurality of color filter dots can reduce the reflected light from the color filter layer. When a plurality of color filter dots are disposed on the color filter layer in each non-aperture region, due to the effect of the plurality of color filter dots, the reflection on the color filter layer in the non-aperture region is reduced, and part of the light is filtered by the plurality of color filter dots and then absorbed by the color filter layer, significantly enhancing the absorption capability of the color filter layer for environmental light. The present application sets a plurality of color filter dots on the surface of the color filter layer, greatly reducing the possibility of ambient light entering the display panel, thereby improving the display quality of the display panel, especially the display image quality under strong light.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel according to a first embodiment of the present application.

FIG. 2 is a schematic diagram of a second type of display panel according to the first embodiment of the present application.

FIG. 3 is a flowchart of a manufacturing method of a display panel according to the present application.

FIG. 4 is a top view schematic diagram of a black matrix according to the present application.

FIG. 5 is a schematic diagram of a display panel according to a second embodiment of the present application.

FIG. 6 is a schematic diagram of a display device according to the present application.

In the drawings: 100, display panel; 101, aperture region; 102, non-aperture region; 110, substrate; 120, light-emitting element; 121, bottom electrode; 122, light-emitting layer; 123, top electrode; 130, pixel-defining layer; 140, encapsulation layer; 141, first inorganic layer; 142, organic layer; 143, second inorganic layer; 150, color filter layer; 151, recess; 160, color filter piece; 161, red filter piece; 162, green filter piece; 163, blue filter piece; 170, black matrix; 180, color filter dot; 181, blue filter dot; 182, transparent filter dot; 190, cover plate; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

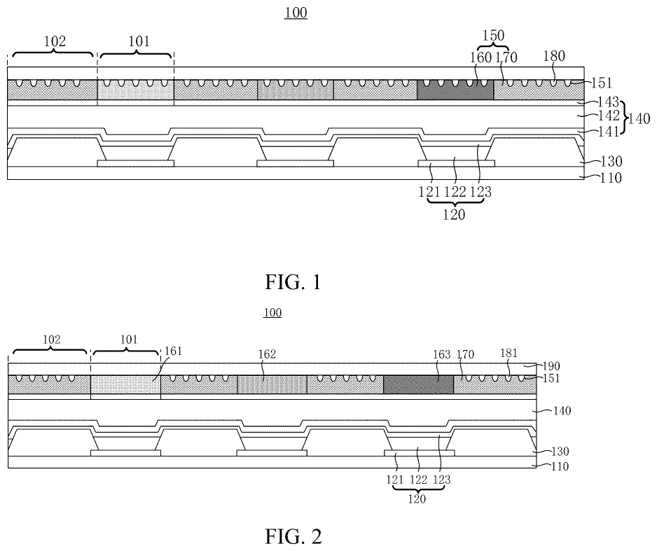

FIG. 1 is a schematic diagram of a display panel according to a first embodiment of the present application. Referring to FIG. 1, the present application discloses a display panel 100. The display panel 100 includes a plurality of aperture regions 101 and a plurality of non-aperture regions 102. The plurality of aperture regions 101 and the plurality of non-aperture regions 102 are mainly divided by a plurality of pixel-defining layers 130. At each opening position formed between the plurality of pixel-defining layers 130, a light-emitting element 120 is correspondingly disposed, where this opening is the corresponding aperture region 101. The position of each pixel-defining layer 130 corresponds to the respective non-aperture region 102.

Specifically, the display panel 100 further includes a substrate 110, a light-emitting element layer, a plurality of pixel-defining layers 130, an encapsulation layer 140, and a color filter layer 150. The light-emitting element layer includes a plurality of light-emitting elements 120. The plurality of light-emitting elements 120 are arranged in an array on the substrate 110, and are respectively disposed within the plurality of aperture regions 101. The plurality of pixel-defining layers 130 are disposed on the substrate 110 and are respectively disposed within the plurality of non-aperture regions 102. Two adjacent light-emitting elements 120 are separated by a corresponding pixel-defining layer 130. The encapsulation layer 140 is disposed on the plurality of light-emitting elements 120 and the plurality of pixel-defining layers 130. The color filter layer 150 is disposed on the encapsulation layer 140. A plurality of color filter dots 180 are arranged on a surface of the color filter layer 150 facing away from the substrate 110. At the same aperture region 101 or the same non-aperture region 102, the color of the color filter dots 180 differs from the color of the color filter layer 150.

In the present application, a plurality of color filter dots 180 are arranged on the surface of the color filter layer 150, and the color of the color filter dots 180 is different from that of the color filter layer 150. When ambient light is incident on the display panel 100, it is first filtered by the plurality of color filter dots 180, thereby reducing the reflective effect on the color filter layer 150. For each aperture region 101, when a plurality of color filter dots 180 are disposed on the color filter layer 150 in this aperture region 101, since the plurality of color filter dots 180 have a different color from that of the color filter layer 150, part of the environmental light is filtered by the color filter dots 180 and then absorbed by the underlying color filter layer 150, so that part of the environmental light cannot enter the display panel 100 and be reflected. Furthermore, the plurality of color filter dots 180 can reduce the reflected light from the color filter layer 150. When a plurality of color filter dots 180 are disposed on the color filter layer 150 in each non-aperture region 102, due to the effect of the plurality of color filter dots 180, the reflection on the color filter layer 150 in the non-aperture region 102 is reduced, and part of the light is filtered by the plurality of color filter dots 180 and then absorbed by the color filter layer 150, significantly enhancing the absorption capability of the color filter layer 150 for environmental light. The present application sets a plurality of color filter dots 180 on the surface of the color filter layer 150, greatly reducing the possibility of ambient light entering the display panel 100, thereby improving the display quality of the display panel 100, especially the display image quality under strong light.

Specifically, the substrate 110 is located at a bottom layer of the display panel 100. A pixel driving layer may be formed on the substrate 110. The pixel driving layer is formed as a stack of multiple metal layers and multiple insulation layers that are laminated together, mainly used for forming a plurality of thin-film transistors and circuits that drive the plurality of light-emitting elements 120 to emit light. A plurality of pixel-defining layers 130 and a light-emitting element layer are formed on the pixel driving layer.

The light-emitting element layer may include a plurality of light-emitting elements 120. Each light-emitting element 120 can emit light of one color, such as red light, green light, blue light, or white light. When multiple light-emitting elements 120 emit red light, green light, and blue light, multiple adjacent light-emitting elements 120 that emit different colors of light combine to form one pixel. For example, multiple pixels can include several red light-emitting elements 120 that emit red light, several green light-emitting elements 120 that emit green light, and several blue light-emitting elements 120 that emit blue light. One pixel may include at least three light-emitting elements 120 of different colors, but is not limited to being composed of light-emitting elements 120 emitting red, green, and blue colors, and may also be composed of various light-emitting elements 120 emitting other colors. Each light-emitting element 120 may include a bottom electrode 121, a light-emitting layer 122, and a top electrode 123. The bottom electrode 121, formed from a metal material, causes ambient light entering the display panel to be reflected by the bottom electrode 121 and emitted from the color filter layer 150, resulting in glare and other issues.

The encapsulation layer 140 may serve to encapsulate the light-emitting element layer to prevent external moisture or oxygen from entering inside the plurality of light-emitting elements 120, which would cause damage to the plurality of light-emitting elements 120. The encapsulation layer 140 may adopt an encapsulating method of laminated inorganic material and organic material. For example, the encapsulation layer 140 may include a first inorganic layer 141, an organic layer 142, and a second inorganic layer 143. The organic layer 142 is disposed between the first inorganic layer 141 and the second inorganic layer 143. The first inorganic layer 141 is disposed to cover the plurality of light-emitting elements 120 and the plurality of pixel-defining layers 130. The color filter layer 150 is disposed on the second inorganic layer 143.

FIG. 2 is a schematic diagram of a second type of display panel according to the first embodiment of the present application. Referring to FIG. 2, in this embodiment, the color filter layer 150 includes a plurality of black matrices 170 and a plurality of color filter pieces 160. The plurality of black matrices 170 are respectively disposed in the plurality of non-aperture regions 102. The plurality of color filter pieces 160 are respectively disposed in the plurality of aperture regions 101. Adjacent color filter pieces 160 are separated by the corresponding black matrix 170. In each non-aperture region 102, the corresponding black matrix 170 has a plurality of recesses 151 formed in the surface facing away from the substrate 110. A plurality of color filter dots 180 are respectively disposed within the plurality of recesses 151. The material of the plurality of color filter dots 180 are identical with the material of any one of the plurality of color filter pieces 160.

In the present application, multiple color filter dots having the same material as any one of the color filter pieces 160 are disposed on each black matrix 170. When ambient light is incident on the display panel 100, and the light strikes the black matrix 170, due to the effect of the multiple color filter dots, the reflection on the black matrix 170 is reduced. After part of the light is filtered by the multiple color filter dots and absorbed by the black matrix 170, the absorption capability of the black matrix 170 for environmental light is significantly improved, causing only a small amount of light to be reflected by the black matrix 170, thereby improving the display quality of the display panel 100, especially the display image quality under strong light.

Specifically, the plurality of color filter dots 181 in this embodiment may be red, green, or blue filter dots. Environmental light may include the entire visible light band or a wide spectrum band. Therefore, when light is incident on the plurality of color filter dots 181 corresponding to each black matrix 170, most of the light can be filtered by the plurality of color filter dots 181, allowing red, green, or blue light to enter the black matrix 170. Since the light is monochromatic and its intensity is weakened after passing through the plurality of color filter dots 181, it is directly absorbed by the black matrix 170, thereby reducing the reflectivity of the black matrix 170.

In another embodiment, the color filter dots 181, besides being filled in the recesses 151 in each black matrix 170, may also be arranged as bumps on each black matrix 170. By arranging color filter bumps, the surface of each black matrix 170 facing away from the substrate 110 becomes uneven, causing part of the light incident on the black matrix 170 to undergo diffuse reflection on the uneven surface. Most of the light is filtered by the color filter bumps and then absorbed by the black matrix 170, thereby greatly reducing the reflection effect of the black matrix 170.

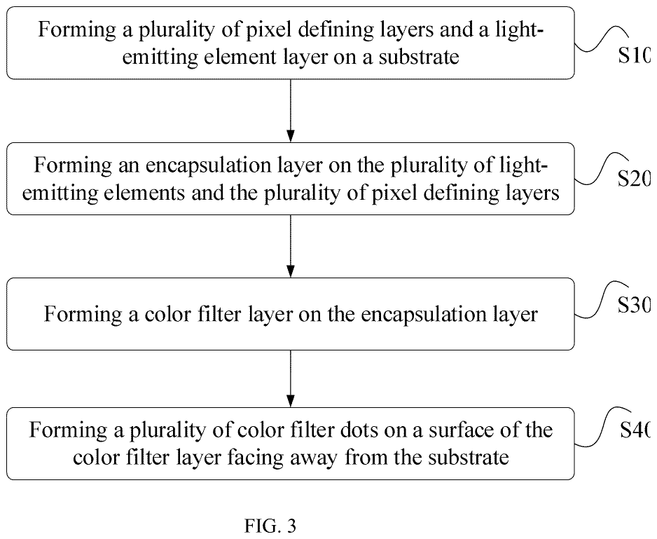

FIG. 3 is a flowchart of a method for manufacturing a display panel according to the present application. Referring to FIG. 3 and FIGS. 1 and 2, the present application further discloses a method for manufacturing a display panel, where the display panel includes a plurality of aperture regions and a plurality of non-aperture regions, and the manufacturing method includes the following operations:
S10: forming a plurality of pixel-defining layers and a light-emitting element layer on a substrate, where the light-emitting element layer includes a plurality of light-emitting elements;
S20: forming an encapsulation layer on the plurality of light-emitting elements and the plurality of pixel-defining layers;
S30: forming a color filter layer on the encapsulation layer; and
S40: forming a plurality of color filter dots on a surface of the color filter layer facing away from the substrate;
where at the same aperture region or the same non-aperture region, a color of the color filter dots differs from a color of the color filter layer.

In the present application, by arranging a plurality of color filter dots 180 on the surface of the color filter layer 150, the likelihood of ambient light entering the display panel 100 is greatly reduced, thereby improving the display quality of the display panel 100, especially the display image quality under strong light conditions.

Specifically, the plurality of color filter dots 180 include a plurality of blue filter dots 181. The plurality of color filter pieces 160 include a plurality of blue filter pieces 163. The plurality of blue filter dots 181 and the plurality of blue filter pieces 163 are formed synchronously in the same manufacturing procedure.

In this embodiment, during the operation of forming the color filter layer 150, the plurality of blue filter pieces 163 may be selected as the final manufacturing procedure. That is, the plurality of black matrixes 170 are first formed, followed by the manufacturing procedure of the plurality of red filter pieces 161 and the manufacturing procedure of the plurality of green filter pieces 162. Finally, when forming the plurality of blue filter pieces 163, the plurality of blue filter dots 181 are synchronously formed on the corresponding black matrix 170 in each non-aperture region 102. The plurality of blue filter dots 181 may be filled within the recesses 151 in the aforementioned black matrix 170 or formed as bumps on the black matrix 170. Moreover, the blue filter dots 181, compared against color filter dots 180 of other colors, have a relatively weak reflected light even if reflection occurs, thus having little impact. Furthermore, during low brightness display or black state of the display panel 100, the blue filter dots 181 are less likely to be noticed by the human eye, thereby reducing color distortion on the display panel 100. Of course, the extent of the impact of the specific color filter dots 180 on the display is also related to the proportion of the color filter dots 180.

In another embodiment, the display panel 100 further includes a cover plate 190. As shown in FIG. 2, the cover plate 190 may be formed on the color filter layer 150. In some manufacturing procedures, the color filter layer 150 may be formed on the cover plate 190. That is, by first forming the color filter layer 150 on the cover plate 190, and then aligning and bonding the cover plate 190 with the substrate 110, the display panel 100 can be formed. That is, a plurality of color filter dots 180 may be formed on the surface of the cover plate 190, where these color filter dots 180 may be formed in each aperture region 101 and/or each non-aperture region 102 depending on actual conditions, followed by the formation of a plurality of black matrix 170, a plurality of color filter pieces 160, and so on.

In this embodiment, no additional manufacturing procedures are required to form multiple recesses 151 in each color filter piece 160 or each black matrix 170. That is, first form multiple color filter dots 180 on the cover plate 190, then form multiple color filter pieces 160 or multiple black matrices 170 on the surface of the cover plate 190 having multiple color filter dots 180, so as to directly cover the multiple color filter dots 180, thereby omitting the manufacturing procedure of forming the aforementioned recesses 151.

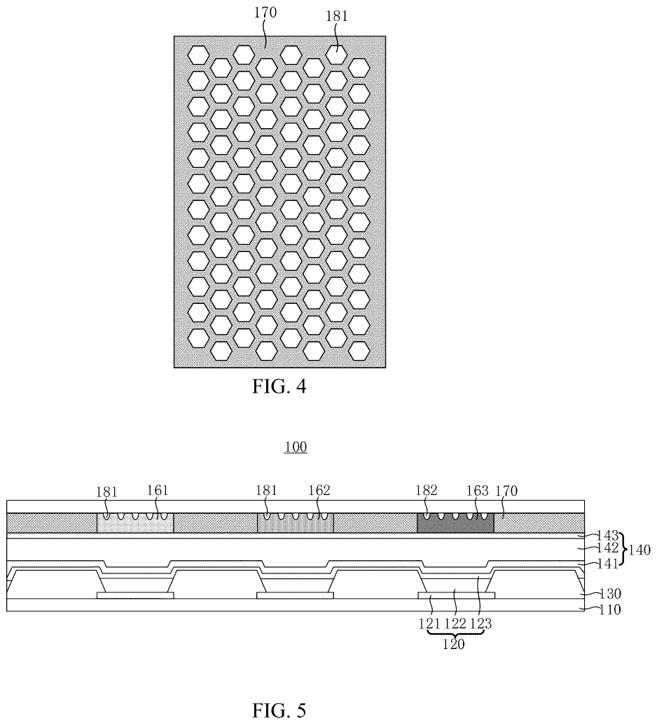

FIG. 4 is a top view schematic diagram of a black matrix according to the present application. Referring to FIG. 4 and FIGS. 1 to 2, the color filter dot 180 may be formed into various shapes, such as hexagonal, circular, or elliptical shapes. In this embodiment, the size of each color filter dot 180 refers to the radial width, such as the distance between two opposite sides of a hexagon, the diameter of a circle, or the major or minor axis of an ellipse as the radial width.

In one non-aperture region 102, the total area of the plurality of color filter dots 180 is less than or equal to two-thirds of the area of the corresponding black matrix 170. When the total area of the plurality of color filter dots 180 is too large, it causes insufficient black state of the display panel 100 under strong light or in a non-display state, leading to a color bias toward the color of the color filter dots 180. For example, when the plurality of color filter dots 180 are blue filter dots 181, if the plurality of blue filter dots 181 on the corresponding black matrix 170 have a large proportion, a bluish tint easily occurs, resulting in a decrease in the quality of the display panel 100. When a certain proportion of blue filter dots 181 are disposed on each black matrix 170, on the one hand, it can reduce light reflection on the black matrix 170 and scatter incident environmental light, and when the coverage area is relatively large, it can minimize the reflected light from the black matrix 170. On the other hand, the reflected light formed by a certain amount of blue filter dots 181 enhances the emission of blue light to some extent, which can address the yellowish tint issue of the display panel 100.

Furthermore, based on the condition that the total area of the plurality of color filter dots 180 meets the aforementioned requirement, the adjacent color filter dots 180 are spaced at least 3 μm apart. Relatively, the color filter dots 180 do not need to be in direct contact with each other. By providing a certain spacing, a larger area of the black matrix 170 can be covered with minimal total dot area, thereby achieving the effect of reducing reflected light from the black matrix 170.

In another embodiment, within one of the non-aperture regions 102, the total number of the color filter dots 180 is fixed. In the width direction of the corresponding black matrix 170, the size of each color filter dot 180 is less than or equal to a ratio α, which is the width of the black matrix 170 divided by the number of color filter dots 180, where the number of color filter dots 180 refers to the total number of color filter dots 180 disposed on the corresponding black matrix 170 within the current non-aperture region 102. For example, if n columns of color filter dots 180 are arranged along the length direction of the black matrix 170, and each column contains m color filter dots 180, then the total number of color filter dots 180 is n×m. When the width of the black matrix 170 is b, the radial width of each color filter dot 180 should be less than or equal to a=b/(n×m). Accordingly, when the radial width of each color filter dot 180 is fixed, the greater the value of n, the smaller the value of m becomes, and vice versa, the smaller the value of n, the greater the value of m. When the values of n and m are fixed, the size of each corresponding color filter dot 180 should not exceed a. As a result, the total area of the plurality of color filter dots 180 within one non-aperture region 102 maintains a fixed proportion relative to the area of the corresponding black matrix 170. Furthermore, in this embodiment, the total area of the plurality of color filter dots 180 relative to the corresponding black matrix 170 may satisfy the two-thirds ratio described in the previous embodiment. That is, the total area of the plurality of color filter dots 180 accounts for two-thirds of the area of the corresponding black matrix 170.

Specifically, the depth of each recess 151 should be less than or equal to half of the thickness of the corresponding black matrix 170. Relatively, the thickness of each black matrix 170 is limited in relation to its light shielding capability. When the thickness of the black matrix 170 is relatively small, its own light shielding capability decreases. However, since a color filter dot 180 is disposed in each recess 151, and the color filter dot 180 has a certain capability to filter light, it can compensate for the insufficient light shielding capability of the black matrix 170 caused by the reduced thickness. The cross-sectional shape of each recess 151 may be semicircular, with a concave bottom surface.

FIG. 5 is a schematic diagram of a display panel according to a second embodiment of the present application. Referring to FIG. 2, the present application discloses a display panel 100. The structure of the display panel 100 in this embodiment is basically the same as that of the previous embodiment, where the difference lies in the color filter layer 150, with further improvements made to the color filter piece 160.

Specifically, the color filter layer 150 includes a plurality of black matrixes 170 and a plurality of color filter pieces 160. The plurality of black matrices 170 are respectively disposed in the plurality of non-aperture regions 102. The plurality of color filter pieces 160 are respectively disposed in the plurality of aperture regions 101. The plurality of color filter pieces 160 include a red filter piece 161, a blue filter piece 163, and a green filter piece 162. When the plurality of light-emitting elements 120 of the display panel 100 are RGB light-emitting elements 120, a red light-emitting element 120 is correspondingly disposed below the red filter piece 161, a blue light-emitting element 120 is disposed below the blue filter piece 163, and a green light-emitting element 120 is disposed below the green filter piece 162. Three adjacent color filter pieces 160 of different colors form one pixel.

Specifically, in the surface of each of the plurality of color filter pieces 160 facing away from the substrate 110 side, a plurality of recesses 151 are formed. The color filter dot 180 is disposed within each of the recesses 151. At the position of the same aperture region 101, the color of each color filter dot 180 differs from the color of the corresponding color filter piece 160.

In this embodiment, multiple color filter dots 180 are arranged on the color filter piece 160. Since the color of the multiple color filter dots 180 differs from that of the corresponding color filter piece 160, part of the environmental light is filtered by the multiple color filter dots 180 and then absorbed by the underlying color filter piece 160, preventing part of the environmental light from entering inside the display panel 100 and causing light reflection. Moreover, the multiple color filter dots 180 can reduce the reflected light from the color filter piece 160.

For normal display, since the proportion of multiple color filter dots 180 on the color filter piece 160 is limited, the impact on the actual display is minimal. On each one of the color filter pieces 160, the proportion of blue filter dots ranges from 8% to 10%. The proportion mentioned here mainly refers to the area ratio, that is, in the orthogonal projection on the substrate, the total projected area of all blue filter dots accounts for 8% to 10% of the projected area of the color filter piece. Within this range, on one hand, the display of the color filter piece 160, including parameters such as color accuracy, is not affected; on the other hand, the presence of multiple color filter dots greatly reduces the reflection of environmental light.

In the present application, multiple color filter dots 180 are disposed on the surface of the color filter layer 150 to greatly reduce the likelihood of environmental light entering the display panel 100, thereby improving the display quality of the display panel 100, especially the display image quality under strong light conditions. Most of the environmental light is scattered by the multiple color filter dots 180, preventing the environmental light from entering the interior of the display panel 100, particularly from reaching the anode of each light-emitting element 120 and causing light reflection, thereby enhancing the display effect.

Specifically, the multiple color filter dots 180 may be blue filter dots 181 or transparent filter dots 182. When the corresponding color filter piece 160 is a red filter piece 161 or a green filter piece 162, the multiple color filter dots 180 may be blue filter dots 181 and transparent filter dots 182. When the corresponding color filter piece 160 is a blue filter piece 163, the multiple color filter dots 180 may be color filter dots 180 of other colors or transparent filter dots 182.

In this embodiment, multiple blue filter dots 181 are respectively arranged at the position of each of the red filter piece 161 and the green filter piece 162. Since the ambient light first passes through the multiple blue filter dots 181, it is filtered by the blue filter dots 181 to form blue light, which is then absorbed by the red filter piece 161 or the green filter piece 162, thereby achieving low-reflection display of the display panel 100 under strong light conditions. When the display panel 100 exhibits a yellowish tint, the multiple blue filter dots 181 arranged on each color filter piece 160 can enhance the proportion of blue light, thereby reducing the yellowish tint of the display panel 100. For the blue filter piece 163, the above low-reflection effect can be achieved by arranging color filter dots 181 of other colors. The transparent filter dot 182 may be formed from the same material as the planar layer. By forming a concave surface between the planar layer and the color filter piece 160, due to the difference in refractive indices between the planar layer and the color filter piece 160, part of the environmental light is scattered by the concave surface and cannot enter the interior of the display panel 100, thereby weakening the environmental light reflection effect at the position of the blue filter piece 163.

Relatively, the scheme of this embodiment can be implemented independently. For example, the scheme where color filter dots 180 are disposed only on the color filter piece 160 and not on the black matrix 170 may also be implemented independently, thereby improving the display effect of the display panel 100 under strong light.

In a specific embodiment, the color filter dot 180 in this embodiment is a blue filter dot 181. Compared against red filter dots and green filter dots, the blue filter dot 181 can transmit blue light and also reflect a small amount of blue light, compensating blue light when the display panel 100 is yellowish, thereby enhancing the display effect of the display panel 100.

In the second embodiment, multiple blue filter dots 181 are arranged at the position of each of the red filter piece 161 and the green filter piece 162. Since the ambient light first passes through the multiple blue filter dots 181 and is filtered to form blue light by these blue filter dots 181, which then enters the red filter piece 161 or green filter piece 162 and is absorbed, thereby achieving a low-reflection display of the display panel 100 under strong light. When the display panel 100 exhibits a yellowish tint, the multiple blue filter dots 181 arranged on the color filter piece 160 can increase the proportion of blue light, thereby reducing the yellowish phenomenon of the display panel 100. For the blue filter piece 163, the above low-reflection effect can be achieved by arranging color filter dots 181 of other colors. By arranging multiple color filter dots 180 on the color filter piece 160, since the color of the color filter dots 180 differs from that of the color filter layer 150, part of the environmental light is filtered by the color filter dots 180 and then absorbed by the underlying color filter layer 150, preventing some environmental light from entering the interior of the display panel 100 and causing light reflection. Moreover, the multiple color filter dots 180 can reduce the reflected light from the color filter layer 150.

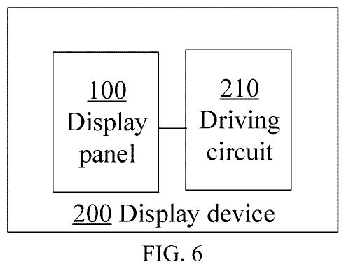

FIG. 6 is a schematic diagram of a display device according to the present application. Referring to FIG. 6, the present application further discloses a display device 200. The display device 200 includes a driving circuit 210 and the display panel 100 according to any one of the above embodiments, where the driving circuit 210 is configured to drive the display panel 100 for display. In the present application, multiple color filter dots 180 are disposed on the surface of the color filter layer 150 to greatly reduce the possibility of environmental light entering the display panel 100, thereby improving the display quality of the display panel 100, especially the display image quality under strong light.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application

What is claimed is:

1. A display panel, comprising a plurality of aperture regions and a plurality of non-aperture regions, the display panel comprising:
a substrate;
a light-emitting element layer, comprising a plurality of light-emitting elements, the plurality of light-emitting elements being arranged in an array on the substrate and respectively disposed within the plurality of aperture regions;
a plurality of pixel-defining layers, disposed on the substrate and respectively located within the plurality of non-aperture regions, wherein every two adjacent light-emitting elements are separated from each other by a corresponding pixel-defining layer;
an encapsulation layer, disposed on the plurality of light-emitting elements and the plurality of pixel-defining layers; and
a color filter layer, disposed on the encapsulation layer;
wherein there are disposed a plurality of color filter dots on a surface of the color filter layer facing away from the substrate, and wherein at each same aperture region or each same non-aperture region, a color of the plurality of color filter dots differs from a color of the color filter layer.

2. The display panel according to claim 1, wherein the color filter layer comprises a plurality of black matrices and a plurality of color filter pieces, the plurality of black matrices being respectively disposed in the plurality of non-aperture regions, the plurality of color filter pieces being respectively disposed in the plurality of aperture regions, wherein every two adjacent color filter pieces are separated from each other by a corresponding black matrix;
wherein within each of the plurality of non-aperture regions, there are defined a plurality of recesses in a surface of the corresponding black matrix facing away from the substrate, and wherein the plurality of color filter dots are respectively disposed within the plurality of recesses, wherein each of the plurality of color filter dots is made of a material identical with a material of any one of the plurality of color filter pieces.

3. The display panel according to claim 2, wherein the plurality of color filter dots comprise transparent filter dots or blue filter dots.

4. The display panel according to claim 2, wherein the plurality of color filter dots comprise a plurality of blue filter dots, wherein the plurality of color filter pieces comprise a plurality of blue filter pieces, and wherein the plurality of blue filter dots and the plurality of blue filter pieces are formed synchronously in a same manufacturing procedure.

5. The display panel according to claim 4, further comprising a cover plate disposed on a side of the color filter layer facing away from the substrate;
wherein the plurality of blue filter dots are formed on the cover plate, and wherein after the plurality of blue filter dots are formed, the plurality of black matrices are formed on the plurality of blue filter dots, so that the plurality of recesses are formed at positions corresponding to the respective blue filter dots on each of the plurality of black matrices.

6. The display panel according to claim 2, wherein a radial width of each of the plurality of color filter dots is less than or equal to a, where a is a ratio of a width of the corresponding black matrix to a number of the plurality of color filter dots distributed on the corresponding black matrix;
wherein an orthogonal projection of each of the plurality of color filter dots on the substrate is hexagonal, circular, or elliptical shaped.

7. The display panel according to claim 2, wherein within each of the plurality of non-aperture regions, a total area of the plurality of color filter dots is less than or equal to two-thirds of an area of the corresponding black matrix;
wherein a spacing between adjacent color filter dots is greater than or equal to 3 μm.

8. The display panel according to claim 1, wherein the color filter layer comprises a plurality of black matrices and a plurality of color filter pieces, the plurality of black matrices being respectively disposed in the plurality of non-aperture regions, the plurality of color filter pieces being respectively disposed in the plurality of aperture regions, and wherein every two adjacent color filter pieces are separated from each other by a corresponding black matrix;
wherein each of the plurality of color filter pieces comprises a plurality of recesses disposed in a surface of the color filter piece facing away from the substrate, and wherein the plurality of color filter dots are respectively disposed within the plurality of recesses;
wherein the plurality of color filter dots are blue filter dots or transparent filter dots.

9. The display panel according to claim 8, wherein on each color filter piece, a total area of respective projections of all blue filter dots on the substrate accounts for 8% to 10% of an area of a projection of the color filter piece on the substrate.

10. The display panel according to claim 1, wherein the plurality of light-emitting elements comprise any one of a red light-emitting element, a green light-emitting element, and a blue light-emitting element.

11. The display panel according to claim 1, wherein the encapsulation layer comprises a first inorganic layer, an organic layer, and a second inorganic layer; wherein the organic layer is disposed between the first inorganic layer and the second inorganic layer, wherein the first inorganic layer is disposed to cover the plurality of light-emitting elements and the plurality of pixel-defining layers, and wherein the color filter layer is disposed on the second inorganic layer.

12. A method for manufacturing a display panel, the display panel comprising a plurality of aperture regions and a plurality of non-aperture regions, the method comprising:
forming a plurality of pixel-defining layers and a light-emitting element layer on a substrate, the light-emitting element layer comprising a plurality of light-emitting elements;
forming an encapsulation layer on the plurality of light-emitting elements and the plurality of pixel-defining layers;
forming a color filter layer on the encapsulation layer; and
forming a plurality of color filter dots on a surface of the color filter layer facing away from the substrate;
wherein at each same aperture region or each same non-aperture region position, a color of the plurality of color filter dots differs from a color of the color filter layer.

13. The method according to claim 12, wherein the plurality of color filter dots comprise a plurality of blue filter dots, wherein the plurality of color filter pieces comprise a plurality of blue filter pieces, and wherein the plurality of blue filter dots and the plurality of blue filter pieces are formed synchronously in a same manufacturing procedure.

14. The method according to claim 12, wherein the color filter layer comprises a plurality of black matrices and a plurality of color filter pieces, the plurality of black matrices being respectively disposed in the plurality of non-aperture regions, the plurality of color filter pieces being respectively disposed in the plurality of aperture regions, and wherein every two adjacent color filter pieces are separated from each other by a corresponding black matrix;
wherein within each of the plurality of non-aperture regions, there are defined a plurality of recesses in a surface of the corresponding black matrix facing away from the substrate, wherein the plurality of color filter dots are respectively disposed within the plurality of recesses, and wherein a material of the plurality of color filter dots is identical with a material of any one of the plurality of color filter pieces.

15. A display device, comprising a driving circuit and a display panel, the driving circuit being configured to drive the display panel for display, the display panel comprising:
a substrate;
a light-emitting element layer, comprising a plurality of light-emitting elements, the plurality of light-emitting elements being arranged in an array on the substrate and respectively disposed within the plurality of aperture regions;
a plurality of pixel-defining layers, disposed on the substrate and respectively located within the plurality of non-aperture regions, wherein every two adjacent light-emitting elements are separated from each other by a corresponding pixel-defining layer;
an encapsulation layer, disposed on the plurality of light-emitting elements and the plurality of pixel-defining layers; and
a color filter layer, disposed on the encapsulation layer;
wherein there are disposed a plurality of color filter dots on a surface of the color filter layer facing away from the substrate, and wherein at each same aperture region or each same non-aperture region, a color of the plurality of color filter dots differs from a color of the color filter layer.

16. The display device according to claim 15, wherein the color filter layer comprises a plurality of black matrices and a plurality of color filter pieces, the plurality of black matrices being respectively disposed in the plurality of non-aperture regions, the plurality of color filter pieces being respectively disposed in the plurality of aperture regions, and wherein every two adjacent color filter pieces are separated from each other by a corresponding black matrix;
wherein within each of the plurality of non-aperture regions, there are defined a plurality of recesses in a surface of the corresponding black matrix facing away from the substrate, and wherein the plurality of color filter dots are respectively disposed within the plurality of recesses, wherein each of the plurality of color filter dots is made of a material identical with a material of any one of the plurality of color filter pieces.

17. The display device according to claim 15, wherein the plurality of color filter dots comprise red filter dots, green filter dots, or blue filter dots.

18. The display device according to claim 17, wherein the plurality of color filter dots comprise a plurality of blue filter dots, wherein the plurality of color filter pieces comprise a plurality of blue filter pieces, and wherein the plurality of blue filter dots and the plurality of blue filter pieces are formed synchronously in a same manufacturing procedure.

19. The display device according to claim 18, wherein the display panel further comprises a cover plate disposed on a side of the color filter layer facing away from the substrate;
wherein the plurality of blue filter dots are formed on the cover plate, and wherein after the plurality of blue filter dots are formed, the plurality of black matrices are formed on the plurality of blue filter dots, so that the plurality of recesses are formed at positions corresponding to the respective blue filter dots on each of the plurality of black matrices.
